(19) United States
(12) Patent Application Publication
(10) Pub. No.: US 2014/0186544 A1
(43) Pub. Date: Jul. 3, 2014

(54) METAL PROCESSING USING HIGH DENSITY PLASMA

(71) Applicant: Applied Materials, Inc., Santa Clara, CA (US)

(72) Inventor: Zhong Qiang Hua, Saratoga, CA (US)

(73) Assignee: APPLIED MATERIALS, INC., Santa Clara, CA (US)

(21) Appl. No.: 13/752,520

(22) Filed: Jan. 29, 2013

Related U.S. Application Data
(60) Provisional application No. 61/748,276, filed on Jan. 2, 2013.
(60) Provisional application No. 61/751,629, filed on Jan. 11, 2013.

(51) Int. Cl. C23C 16/505

(52) U.S. Cl. CPC C23C 16/505
USPC 427/534

(57) ABSTRACT

Methods of forming dielectric layers using high-density plasma chemical vapor deposition are described. Dielectric layers are formed over metal films. The metal film is present on a substrate prior to entering the high-density plasma processing chamber. The metal film is processed to remove oxidation and optionally to improve adhesion of the dielectric layer on the metal film.

This application claims the benefit of U.S. Prov Pat. App. No. 61/748,276 filed Jan. 2, 2013, and titled “METAL PROCESSING USING HIGH DENSITY PLASMA,” as well as U.S. Prov Pat. App. No. 61/751,629 filed Jan. 11, 2013, and titled “SILICON NITRIDE GAPFILL IMPLEMENTING HIGH DENSITY PLASMA.” Each of the above applications is hereby entirely incorporated herein by reference for all purposes.

### BACKGROUND OF THE INVENTION

Conventional thermal CVD processes supply reactive gases to the substrate surface where the heat from the surface induces chemical reactions to produce a film. Improvements in deposition rate and film properties have been achieved through the use of plasma sources to assist the chemical reactions. Plasma enhanced CVD (“PECVD”) techniques promote excitation, dissociation, and ionization of the reactant gases by the application of radio frequency (“RF”) energy to a reaction zone near the substrate surface, thereby creating a plasma. The high reactivity of the species in the plasma reduces the energy required to activate a chemical reaction. This effectively lowers the substrate temperature required for PECVD processes as compared to conventional thermal CVD processes. Reducing the substrate temperature is attractive because it lowers the chances of diffusion or other mass transport effects which may cause a reduction in the yield of the manufacturing process.

Further improvements have been enabled by high density plasma (“HDP”) CVD techniques, in which a dense plasma is formed at low vacuum pressures so that the plasma species are even more reactive. HDP-CVD allows the use of lower partial pressures of reactant gases while maintaining a higher ionic concentration. HDP-CVD also allows the accelerating energy to be controlled independently of the ionization energy. There are a number of material changes that result from depositing films with a high density plasma in addition to distinctions associated with patterned wafer processing. When films are deposited with HDP-CVD method the resultant film may possess a higher density than other CVD methods.

High density films are useful for etch stops, polishing stops and seals against molecular diffusion either during processing or during operation of an integrated circuit. Silicon nitride, for example, has been used as a barrier layer between a premetal dielectric layer and the semiconductor substrate. New processing techniques are needed to broaden the range of applications for high density films.

### BRIEF SUMMARY OF THE INVENTION

Methods of forming dielectric layers using high-density plasma chemical vapor deposition are described. Dielectric layers are formed over metal films. The metal film is present on a substrate prior to entering the high-density plasma processing chamber. The metal film is processed to remove oxidation and to improve adhesion of the dielectric layer to the metal film.

Embodiments of the invention include methods for depositing a dielectric layer on a metal surface of a substrate in a substrate processing region of a substrate processing chamber. The methods include the sequential steps of transferring the substrate into the substrate processing region. The methods further include deoxidizing the substrate with a deoxidation high-density plasma to remove an oxidation layer. The deoxidation high-density plasma comprises hydrogen (H) but is silicon-free, carbon-free, nitrogen-free, fluorine-free and oxygen-free. The methods further include forming the dielectric layer on the substrate in the same substrate processing region used for treating the substrate by forming a deposition high density plasma in the substrate processing region from a deposition process gas comprising a silicon source. The methods further include removing the substrate from the substrate processing region.

Additional embodiments and features are set forth in part in the description that follows, and in part will become apparent to those skilled in the art upon examination of the specification or may be learned by the practice of the disclosed embodiments. The features and advantages of the disclosed embodiments may be realized and attained by means of the instrumentalities, combinations, and methods described in the specification.

### BRIEF DESCRIPTION OF THE DRAWINGS

A further understanding of the nature and advantages of the disclosed embodiments may be realized by reference to the remaining portions of the specification and the drawings.

FIG. 1 is a flow chart indicating selected steps in growing a silicon nitride film according to disclosed embodiments.

FIG. 2A is a simplified diagram of one embodiment of a high-density-plasma chemical-vapor-deposition system according to embodiments of the invention.

FIG. 2B is a simplified cross section of a gas ring that may be used in conjunction with the exemplary processing system of FIG. 2A.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION OF THE INVENTION

Methods of forming dielectric layers using high-density plasma chemical vapor deposition are described. Dielectric layers are formed over metal films. The metal film is present on a substrate prior to entering the high-density plasma processing chamber. The metal film is processed to remove oxidation and to improve adhesion of the dielectric layer on the metal film.

Methods of depositing dielectric layers on metal surfaces of substrates have been developed using high-density plasma techniques. Methods of conformally depositing dielectric layers on patterned substrates have been developed in order to prevent molecular migration into the metal surfaces, thus retaining the conductivity and reliability of devices made using these techniques. Applying zero or relatively low bias power during deposition has been found to reduce stress and enable the conformal coverage of high aspect ratio trenches. A hydrogen plasma treatment has been found to remove oxidation from the metal surfaces of the substrates prior to forming the dielectric layer. The hydrogen plasma treatment, thereby, increases adhesion of the dielectric layer and improves performance of completed devices. These high density plasma chemical vapor deposition (HDP-CVD) techniques may be used to provide a hermetic seal and to create a desirable passivation layer protecting the metal surface from corrosion and other deterioration.

As used herein, a high-density-plasma process is a plasma CVD process that employs a plasma having an ion density on the order of 10¹¹ ions/cm³ or greater. A high-density plasma may also have an ionization fraction (ion/neutral ratio) on the order of 10⁻⁴ or greater. Typically HDP-CVD processes include simultaneous deposition and sputtering components. Some HDP-CVD processes embodied in the present invention are different from traditional HDP-CVD processes which are typically optimized for gap-fill. In some steps and embodiments, conformal dielectric films are achieved with substantially reduced (<10% of total plasma power) substrate bias power and thus create less sputtering than HDP-CVD processes that employ significant bias power. Despite this departure from traditional HDP process parameters, a scalar characterization involving sputtering and deposition rates will be useful and is defined below.

The relative levels of the combined deposition and sputtering characteristics of a high-density plasma may depend on such factors as the gas flow rates used to provide the gaseous mixture, the source power levels applied to maintain the plasma, the bias power applied to the substrate, and the like. A combination of these factors may be conveniently characterized by a “deposition-to-sputter ratio” defined as

$$\frac{( net deposition rate ) + ( blanket sputtering rate )}{( blanket sputtering rate )}$$

The deposition-to-sputter ratio increases with increased deposition and decreases with increased sputtering. As used in the definition of the deposition-to-sputter ratio, the “net deposition rate” refers to the deposition rate that is measured when deposition and sputtering are occurring simultaneously. The “blanket sputter rate” is the sputter rate measured when the process recipe is run without deposition gases (leaving nitrogen and a fluent for example). The flow rates of the remaining gases are increased, maintaining fixed ratios among them, to attain the pressure present in the process chamber during normal processing.

Other functionally equivalent measures may be used to quantify the relative deposition and sputtering contributions of the HDP process, as is known to those of skill in the art. A common alternative ratio is the “etching-to-deposition ratio”

$$\frac{( source \text{-} only deposition rate ) + ( net deposition rate )}{( source \text{-} only deposition rate )}$$

which increases with increased sputtering and decreases with increased deposition. As used in the definition of the etching-to-deposition ratio, the “net deposition rate” again refers to the deposition rate measured when deposition and sputtering are occurring simultaneously. The “source-only deposition rate,” however, refers to the deposition rate that is measured when the process recipe is run with no sputtering. Embodiments of the invention are described herein in terms of deposition-to-sputter ratios. While deposition-to-sputter and etching-to-deposition ratios are not precise reciprocals, they are inversely related and conversion between them will be understood to those of skill in the art.

Typical HDP-CVD processes are geared towards the gap-fill of trench geometries. In gapfill processes, a substrate bias RF power is used to accelerate ions toward the substrate which produces a narrow range of approach trajectories. This narrowing combined with sputtering activity allows gaps to be filled before the top corners of a growing via come together to form and maintain a void. Deposition-to-sputter ratios (D:S) in such gap fill applications may range from about 3:1 to about 10:1, for example, with some exotic applications having deposition-to-sputter ratios to about 25:1, for example. Dielectric films grown according to embodiments of the present invention may be produced with an HDP-CVD process using relatively little substrate bias power. The blanket sputtering rate useful for characterization of D:S under these conditions may be low and the deposition-to-sputter ratio can generally be expected to be above or about 25:1, above or about 50:1, above or about 75:1 or above or about 100:1 in disclosed embodiments.

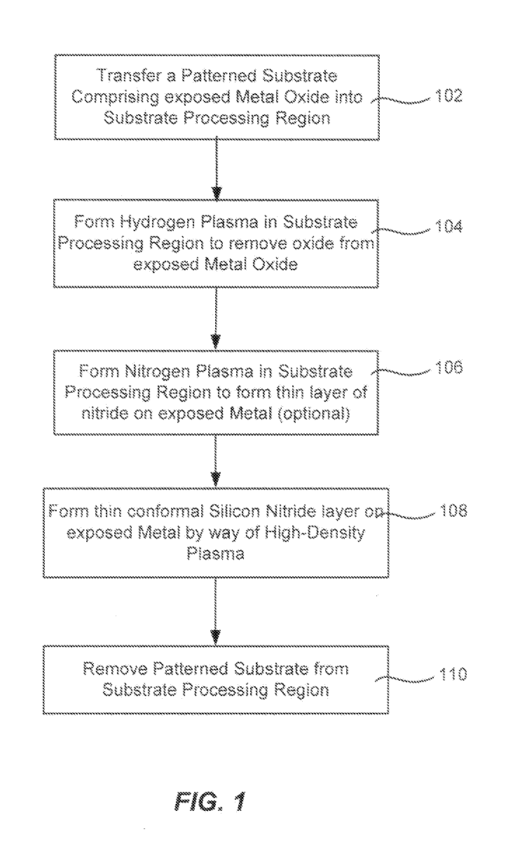

In order to better understand and appreciate the invention, reference is now made to FIG. 1 which is a flow chart indicating selected steps in forming a conformal dielectric silicon nitride film according to embodiments of the invention. The silicon nitride formation process begins when a patterned substrate having a trench is transferred into a substrate processing region (operation 102). Hydrogen (H₂) is introduced into the substrate processing region and a high density plasma is formed (operation 104) to pretreat the surface of the patterned substrate before conformal silicon nitride is deposited. This pretreatment deoxidizes an exposed metal surface on the patterned substrate and enhances the hermetic seal created by the silicon nitride passivation layer. The deoxidation of the thin metal oxidation layer is thought to result from the presence of activated hydrogen in the high-density plasma. The activated hydrogen may bond with surface-resident oxygen and near surface oxygen to create complexes which desorb and exhaust from the substrate processing region. The removal of oxidation is enabled, in part, from the lack of deposition precursors in the deoxidation high-density plasma. The deoxidation high-density plasma is silicon-free, carbon-free, nitrogen-free, fluorine-free and oxygen-free. The deoxidation high-density plasma consists only of hydrogen and inert gases in embodiments of the invention.

The metal surface underlying the layer of oxidation (which was removed in step 104) may include copper, aluminum or tungsten in disclosed embodiments. More generally, the metal surface may have an electrical resistivity below or about one hundred nanoohm-meters, below or about seventy five nanoohm-meters, below or about fifty nanoohm-meters, or below or about twenty five nanoohm-meters in embodiments of the invention.

Optionally, an interfacial preparation step (step 106) is included following the deoxidation of the substrate, which occurred in step 104. The interfacial preparation step includes treating the substrate with an interfacial high-density plasma, in which the interfacial high-density plasma includes hydrogen (H) and nitrogen (N) formed from an interfacial preparation process gas. The inventors have found that the interfacial high-density plasma ought to be fluorine-free in order to improve chemical combatibility with the underlying metal surface. As such, fluorine is absent from the previous deoxidation step as well. Ammonia or hydrazine may be flowed to the substrate processing region (the high-density plasma region) as the sources of hydrogen (H) and nitrogen (N) in embodiments of the invention. Alternatively, molecular hydrogen (H₂) and molecular nitrogen (N₂) may be flowed to the high-density plasma region to form the interfacial high-density plasma which includes hydrogen (H) and nitrogen (N).

A dielectric layer of silicon nitride is then formed on the substrate (step 108) in the same substrate processing region used for both the deoxidation pretreatment step and the optional interfacial preparation step. The formation of the silicon nitride is effected by forming a deposition high density plasma in the substrate processing region from a deposition process gas comprising a silicon source (SiH₄) and a nitrogen source (N₂). Other sources of silicon and nitrogen may be used and combination silicon-nitrogen-sources may also be used in lieu of, or to augment the separate deposition sources. The substrate is then removed from the substrate processing region in step 110.

The process gas mixture provides a source of nitrogen and silicon which form the silicon nitride film on the substrate. The precursor gases may include a silicon-containing gas, such as silane (SiH₄), and a nitrogen (N) containing gas such as molecular nitrogen (N₂). Other gases can certainly be used. Molecules comprising both silicon and nitrogen are available and can be used as one or more of the precursor gases. In disclosed embodiments, the silicon and nitrogen sources are introduced through different delivery channels so that they begin mixing near or in the reaction region. An inert gas or fluent gas may also be introduced to facilitate the production of ionic species from the other components of the process gas mixture. For example, argon is more easily ionized than N₂ and, in an embodiment, can provide electrons to the plasma which then assist in the dissociation and ionization of the N₂. This effect increases the probability of chemical reactions and the rate of deposition. The fluent may be introduced through the same delivery channel as either or both the silicon and nitrogen sources or through a different channel altogether.

Little or no plasma bias power is applied between the high-density plasma and the substrate to accelerate ions toward the substrate in operation 108. As a result, conformal (or predominantly conformal) silicon nitride is formed on the substrate. The substrate bias power may be zero, below 100 watts, below 200 watts, below 300 watts or below 500 watts in disclosed embodiments. Little or no plasma bias power (such as represented in these embodiments) has been found by the inventors to result in passivating conformal silicon nitride formed on the substrate. These bias powers have been found to achieve the deposition-to-sputter ratios outlined earlier in the discussion of FIG. 1. Performing silicon nitride deposition in this manner on patterned substrates having high aspect ratio metal-lined trenches (such as those found in MRAM and a variety of other applications) results in a conformal protective silicon nitride layer which protects the metal from chemical attack or migration.

Forming conformal dielectric according to the methods herein enables the process to be conducted at relatively low substrate temperatures. Whereas typical thermal dielectric deposition processes may be carried out at substrate temperatures of 650° C. or more, the substrate temperatures used during formation of HDP dielectric may be below or about 500° C., below or about 450° C. or below or about 400° C. in embodiments of the invention. The temperature of the substrate may be controlled in a variety of ways. In the methods described herein, the substrate may be heated to the deposition temperature using the hydrogen plasma. In situations where the plasmas would raise the substrate temperature above these ranges, the back of the substrate may be cooled by a backside flow of helium.

Silane is not the only silicon source useful for forming silicon-based dielectric films such as silicon nitride. Disilane and higher order silanes would also be able to form these films, as would silanes having one or more double bond between adjacent silicon atoms. Silanes used to form silicon (and silicon-containing dielectrics in general) are devoid of halogens, in embodiments of the invention, to avoid the incorporation of halogens in the forming film. In general, these silicon sources may be used alone or combined in any combination with one another and referred to collectively as the deposition process gas.

It has been found that ammonia (NH₃) is a useful source of nitrogen for the interfacial preparation step. The inventors have also found that using hydrazine (N₂H₄) and other nitrogen-and-hydrogen-containing compounds work as inputs to the interfacial high-density plasma. Molecular nitrogen (N₂) has also been found to provide for production worthy adhesion of the subsequent silicon nitride dielectric layer to the metal surface of the substrate. Molecular nitrogen may be combined with a hydrogen source to produce chemically similar results to ammonia or hydrazine.

With respect to forming the dielectric layer, the dielectric layer may be a silicon-containing dielectric layer of silicon oxide, silicon oxynitride, silicon oxycarbide, silicon nitride, silicon carbide or silicon carbon nitride. The dielectric layer may be generally conformal, in embodiments, and may be less than or about ten nanometers in thickness. High-density plasmas are not sensitive to the type of chemicals used to feed the plasma, and therefore there is considerable latitude in the choice of the precursors used to form each of these silicon-containing dielectric films. The deposition process gas may include at least one of a nitrogen source, an oxygen source or a carbon source. The carbon containing films may be formed using any of a variety of hydrocarbons (e.g. CH₄, C₂H₆, C₃H₈ etc.). The oxygen containing films may be formed using any of a variety of oxygen precursors such as O₂, O₃, H₂O and the like. Precursors containing oxygen and nitrogen, oxygen and carbon or nitrogen and carbon may be used, in disclosed embodiments when forming the tertiary dielectric layers listed above. Generally speaking, the silicon nitride in the above example may be a silicon-containing dielectric layer.

Any of the process gases referred to herein may be combined with inert gases which may assist in stabilizing the high-density plasma or improving the uniformity of the conformal dielectric deposition across a substrate. Argon, neon and/or helium are added to these process gases in embodiments of the invention and will be referred to as fluent gases or inert gases. Fluent gases may be introduced during one or more of the steps to alter (e.g., increase) the plasma density or stability. Increasing the plasma density may help to increase the ionization and dissociation probabilities within the plasma.

Lowering hydrogen content within silicon-containing dielectric layers has been correlated with better sealing ability against chemical migration into the metal surface. Hydrogen content may be lowered by reducing the hydrogen available in the precursors delivered to the high-density plasma. For example, molecular nitrogen (N₂) may be used in place of ammonia (NH₃) during the forming of the dielectric layer. Maintaining a low pressure in the reaction region also helps maintain low hydrogen content. An increase in the pressure reduces the mean free path and therefore changes the ionization fraction and gas-phase dynamics, hampering the removal of the hydrogen from the silicon nitride network during formation. The pressure in the reaction region may be at or below 50 mTorr, at or below 40 mTorr, at or below 25 mTorr, at or below 15 mTorr, at or below 10 mTorr or at or below 5 mTorr in disclosed embodiments. These pressures in the substrate processing region may also form the process pressure embodiments for the deoxidation step and also the interfacial treatment step. The substrate temperatures outlined below also apply to all processing steps described herein.

The substrate temperature is maintained at or below 600° C., 500° C. or 450° C. in disclosed embodiments. The RF power supplied to the substrate processing region to create the high-density plasma will be described in more detail later, however, the total RF power may be greater than about 5,000 watts and less than or about 13,000 watts in embodiments of the invention while forming the dielectric layer. These powers are lower than for typical silicon oxide deposition conditions, and the difference can be ascribed to the greater compressive stress displayed by silicon nitride when deposited by high-density plasma chemical vapor deposition. The inventors have discovered that operating at total RF powers in the 5 kW to 13 kW range during the formation of the silicon nitride layer reduces the film stress which further improves adhesion of the silicon nitride layers. In an embodiment, the substrate is biased from the deposition high density plasma with no deposition bias power or at least a relatively small amount of bias power (e.g. less than about 500 watts).

With regard to the other steps in the process, forming the deoxidation high-density plasma may include applying RF power between about 5,000 watts and about 20,000 watts to the substrate processing region while deoxidizing the substrate. The wider process window is enabled by the lack of a forming film. Consequently, no stress considerations are present and higher plasma powers are not going to negatively impact the process. The deoxidation high density plasma may be biased relative to the substrate using a deoxidation bias power of zero, below or about 100 watts, below or about 200 watts, below or about 300 watts or below or about 500 watts while deoxidizing the substrate in embodiments of the invention. Similarly, treating the substrate with the interfacial preparation step may include applying an interfacial high-density plasma in the RF frequencies with total plasma power between about 5,000 watts and about 20,000 watts to the substrate processing region while treating the substrate. The interfacial high density plasma may be biased relative to the substrate using a interfacial bias power of zero, below or about 100 watts, below or about 200 watts, below or about 300 watts or below or about 500 watts while deoxidizing the substrate in embodiments of the invention.

Generally speaking, the processes described herein may be used to describe films which contain silicon and nitrogen (and not just silicon nitride). The remote plasma etch processes may remove silicon nitride which includes an atomic concentration of about 30% or more silicon and about 45% or more nitrogen in embodiments of the invention. The remote plasma etch processes may remove silicon nitride which includes an atomic concentration of about 40% or more silicon and about 55% or more nitrogen in disclosed embodiments. The silicon-and-nitrogen-containing material may also consist essentially of silicon and nitrogen, allowing for small dopant concentrations and other undesirable or desirable minority additives.

Additional process parameters are disclosed in the course of describing an exemplary processing chamber and system.

### Exemplary Substrate Processing System

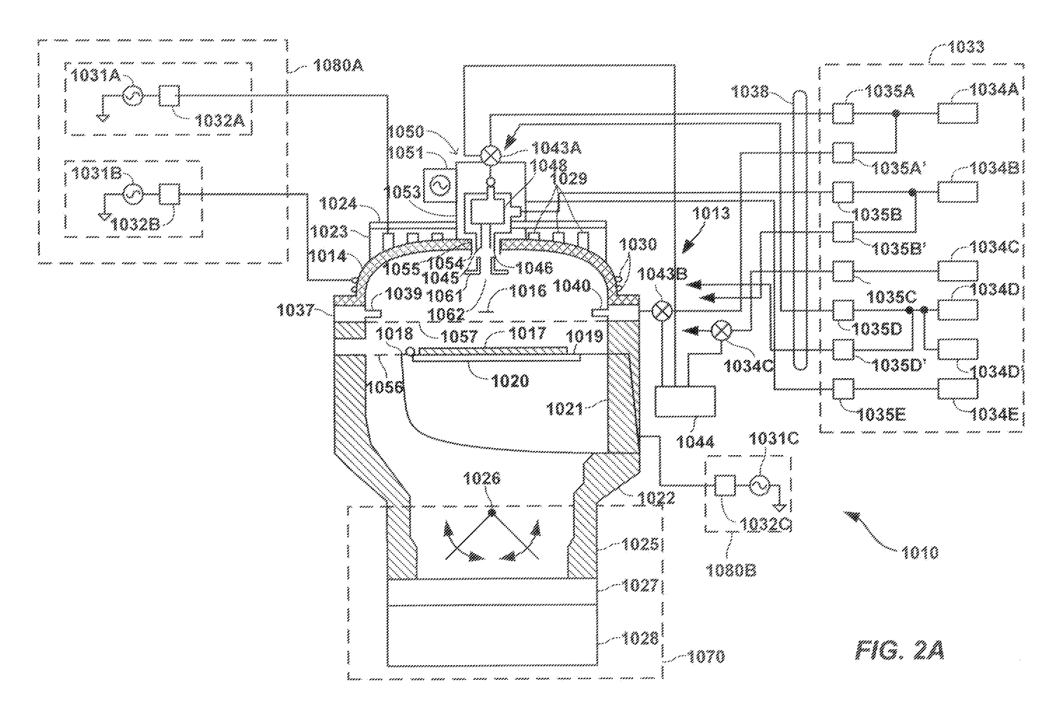

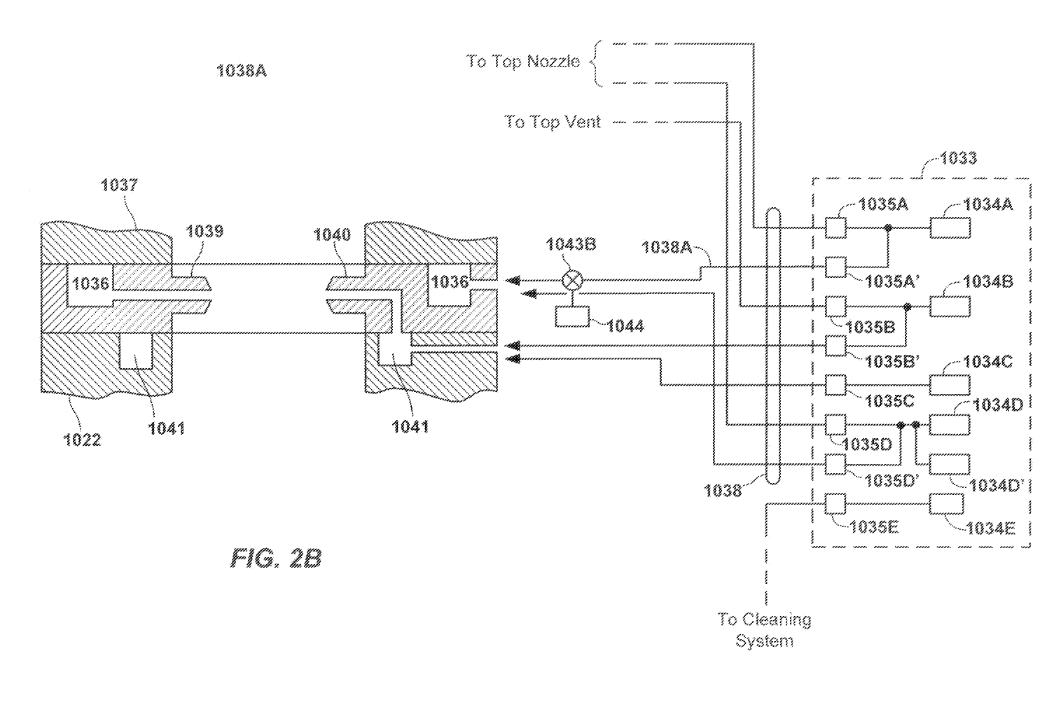

The inventors have implemented embodiments of the invention with the ULTIMA™ system manufactured by APPLIED MATERIALS, INC., of Santa Clara, Calif., a general description of which is provided in commonly assigned U.S. Pat. No. 6,170,428, “SYMMETRIC TUNABLE INDUCTIVELY COUPLED HDP-CVD REACTOR,” filed Jul. 15, 1996 by Fred C. Redeker, Farhad Moghadam, Hirogi Hanawa, Tetsuya Ishikawa, Dan Maydan, Shijian Li, Brian Lue, Robert Steger, Yaxin Wang, Manus Wong and Ashok Sinha, the entire disclosure of which is incorporated herein by reference. An overview of the system is provided in connection with FIGS. 2A-2B below. FIG. 2A schematically illustrates the structure of such an HDP-CVD system 1010 in an embodiment. The system 1010 includes a chamber 1013, a vacuum system 1070, a source plasma system 1080A, a substrate bias plasma system 1080B, a gas delivery system 1033, and a remote plasma cleaning system 1050.

The upper portion of chamber 1013 includes a dome 1014, which is made of a ceramic dielectric material, such as aluminum oxide or aluminum nitride. Dome 1014 defines an upper boundary of a plasma processing region 1016. Plasma processing region 1016 is bounded on the bottom by the upper surface of a substrate 1017 and a substrate support member 1018.

A heater plate 1023 and a cold plate 1024 surmount, and are thermally coupled to, dome 1014. Heater plate 1023 and cold plate 1024 allow control of the dome temperature to within about 10° C. over a range of about 100° C. to 200° C. This allows optimizing the dome temperature for the various processes. For example, it may be desirable to maintain the dome at a higher temperature for cleaning or etching processes than for deposition processes. Accurate control of the dome temperature also reduces the flake or particle counts in the chamber and improves adhesion between the deposited layer and the substrate.

The lower portion of chamber 1013 includes a body member 1022, which joins the chamber to the vacuum system. A base portion 1021 of substrate support member 1018 is mounted on, and forms a continuous inner surface with, body member 1022. Substrates are transferred into and out of chamber 1013 by a robot blade (not shown) through an insertion/removal opening (not shown) in the side of chamber 1013. Lift pins (not shown) are raised and then lowered under the control of a motor (also not shown) to move the substrate from the robot blade at an upper loading position 1057 to a lower processing position 1056 in which the substrate is placed on a substrate receiving portion 1019 of substrate support member 1018. Substrate receiving portion 1019 includes an electrostatic chuck 1020 that secures the substrate to substrate support member 1018 during substrate processing. In a preferred embodiment, substrate support member 1018 is made from an aluminum oxide or aluminum ceramic material.

Vacuum system 1070 includes throttle body 1025, which houses twin-blade throttle valve 1026 and is attached to gate valve 1027 and turbo-molecular pump 1028. It should be noted that throttle body 1025 offers minimum obstruction to gas flow, and allows symmetric pumping. Gate valve 1027 can isolate pump 1028 from throttle body 1025, and can also control chamber pressure by restricting the exhaust flow capacity when throttle valve 1026 is fully open. The arrangement of the throttle valve, gate valve, and turbo-molecular pump allow accurate and stable control of chamber pressures up to about 1 mTorr to about 2 Torr.

The source plasma system 1080A includes a top coil 1029 and side coil 1030, mounted on dome 1014. A symmetrical ground shield (not shown) reduces electrical coupling between the coils. Top coil 1029 is powered by top source RF (SRF) generator 1031A, whereas side coil 1030 is powered by side SRF generator 1031B, allowing independent power levels and frequencies of operation for each coil. This dual coil system allows control of the radial ion density in chamber 1013, thereby improving plasma uniformity. Side coil 1030 and top coil 1029 are typically inductively driven, which does not require a complimentary electrode. In a specific embodiment, the top source RF generator 1031A provides up to 5,000 watts of RF power at nominally 2 MHz and the side source RF generator 1031B provides up to 7,500 watts of RF power at nominally 2 MHz. The operating frequencies of the top and side RF generators may be offset from the nominal operating frequency (e.g. to 1.7-1.9 MHz and 1.9-2.1 MHz, respectively) to improve plasma-generation efficiency.

A substrate bias plasma system 1080B includes a bias RF (“BRF”) generator 1031C and a bias matching network 1032C. The bias plasma system 1080B capacitively couples substrate portion 1017 to body member 1022, which act as complimentary electrodes. The bias plasma system 1080B serves to enhance the transport of plasma species (e.g., ions) created by the source plasma system 1080A to the surface of the substrate. In a specific embodiment, the substrate bias RF generator provides up to 10,000 watts of RF power at a frequency of about 13.56 MHz.

RF generators 1031A and 1031B include digitally controlled synthesizers. Each generator includes an RF control circuit (not shown) that measures reflected power from the chamber and coil back to the generator and adjusts the frequency of operation to obtain the lowest reflected power, as understood by a person of ordinary skill in the art. RF generators are typically designed to operate into a load with a characteristic impedance of 50 ohms. RF power may be reflected from loads that have a different characteristic impedance than the generator. This can reduce power transferred to the load. Additionally, power reflected from the load back to the generator may overload and damage the generator. Because the impedance of a plasma may range from less than 5 ohms to over 900 ohms, depending on the plasma ion density, among other factors, and because reflected power may be a function of frequency, adjusting the generator frequency according to the reflected power increases the power transferred from the RF generator to the plasma and protects the generator. Another way to reduce reflected power and improve efficiency is with a matching network.

Matching networks 1032A and 1032B match the output impedance of generators 1031A and 1031B with their respective coils 1029 and 1030. The RF control circuit may tune both matching networks by changing the value of capacitors within the matching networks to match the generator to the load as the load changes. The RF control circuit may tune a matching network when the power reflected from the load back to the generator exceeds a certain limit. One way to provide a constant match, and effectively disable the RF control circuit from tuning the matching network, is to set the reflected power limit above any expected value of reflected power. This may help stabilize a plasma under some conditions by holding the matching network constant at its most recent condition.

Other measures may also help stabilize a plasma. For example, the RF control circuit can be used to determine the power delivered to the load (plasma) and may increase or decrease the generator output power to keep the delivered power substantially constant during deposition of a layer.

A gas delivery system 1033 provides gases from several sources, 1034A-334E to a chamber for processing the substrate by way of gas delivery lines 1038 (only some of which are shown). As would be understood by a person of skill in the art, the actual sources used for sources 1034A-1034E and the actual connection of delivery lines 1038 to chamber 1013 varies depending on the deposition and cleaning processes executed within chamber 1013. Gases are introduced into chamber 1013 through a gas ring 1037 and/or a top nozzle 1045. FIG. 2B is a simplified, partial cross-sectional view of chamber 1013 showing additional details of gas ring 1037.

In one embodiment, first and second gas sources, 1034A and 1034B, and first and second gas flow controllers, 1035A′ and 1035B′, provide gas to ring plenum 1036 in gas ring 1037 by way of gas delivery lines 1038 (only some of which are shown). Gas ring 1037 has a plurality of source gas nozzles 1039 (only one of which is shown for purposes of illustration) that provide a uniform flow of gas over the substrate. Nozzle length and nozzle angle may be changed to allow tailoring of the uniformity profile and gas utilization efficiency for a particular process within an individual chamber. In a preferred embodiment, gas ring 1037 has 12 source gas nozzles made from an aluminum oxide ceramic.

Gas ring 1037 also has a plurality of oxidizer gas nozzles 1040 (only one of which is shown), which in one embodiment are co-planar with and shorter than source gas nozzles 1039, and in one embodiment receive gas from body plenum 1041. In some embodiments it is desirable not to mix source gases and oxidizer gases before injecting the gases into chamber 1013. In other embodiments, oxidizer gas and source gas may be mixed prior to injecting the gases into chamber 1013 by providing apertures (not shown) between body plenum 1041 and gas ring plenum 1036. In one embodiment, third, fourth, and fifth gas sources, 1034C, 1034D, and 1034D′, and third and fourth gas flow controllers, 1035C and 1035D′, provide gas to body plenum by way of gas delivery lines 1038. Additional valves, such as 1043B (other valves not shown), may shut off gas from the flow controllers to the chamber. In implementing certain embodiments of the invention, source 1034A comprises a silane SiH₄ source, source 1034B comprises a molecular nitrogen N₂ source, source 1034C comprises a TSA source, source 1034D comprises an argon Ar source, and source 1034D′ comprises a disilane Si₂H₆ source.

In embodiments where flammable, toxic, or corrosive gases are used, it may be desirable to eliminate gas remaining in the gas delivery lines after a deposition. This may be accomplished using a 3-way valve, such as valve 1043B, to isolate chamber 1013 from delivery line 1038A and to vent delivery line 1038A to vacuum foreline 1044, for example. As shown in FIG. 2A, other similar valves, such as 1043A and 1043C, may be incorporated on other gas delivery lines. Such three-way valves may be placed as close to chamber 1013 as practical, to minimize the volume of the unvented gas delivery line (between the three-way valve and the chamber). Additionally, two-way (on-off) valves (not shown) may be placed between a mass flow controller (“MFC”) and the chamber or between a gas source and an MFC.

Referring again to FIG. 2A, chamber 1013 also has top nozzle 1045 and top vent 1046. Top nozzle 1045 and top vent 1046 allow independent control of top and side flows of the gases, which improves film uniformity and allows fine adjustment of the film's deposition and doping parameters. Top vent 1046 is an annular opening around top nozzle 1045. In one embodiment, first gas source 1034A supplies source gas nozzles 1039 and top nozzle 1045. Source nozzle MFC 1035A′ controls the amount of gas delivered to source gas nozzles 1039 and top nozzle MFC 1035A controls the amount of gas delivered to top gas nozzle 1045. Similarly, two MFCs 1035B and 1035B′ may be used to control the flow of oxygen to both top vent 1046 and oxidizer gas nozzles 1040 from a single source of oxygen, such as source 1034B. In some embodiments, oxygen is not supplied to the chamber from any side nozzles. The gases supplied to top nozzle 1045 and top vent 1046 may be kept separate prior to flowing the gases into chamber 1013, or the gases may be mixed in top plenum 1048 before they flow into chamber 1013. Separate sources of the same gas may be used to supply various portions of the chamber.

A remote microwave-generated plasma cleaning system 1050 is provided to periodically clean deposition residues from chamber components. The cleaning system includes a remote microwave generator 1051 that creates a plasma from a cleaning gas source 1034E (e.g., molecular fluorine, nitrogen trifluoride, other fluorocarbons or equivalents) in reactor cavity 1053. The reactive species resulting from this plasma are conveyed to chamber 1013 through cleaning gas feed port 1054 by way of applicator tube 1055. The materials used to contain the cleaning plasma (e.g., cavity 1053 and applicator tube 1055) must be resistant to attack by the plasma. The distance between reactor cavity 1053 and feed port 1054 should be kept as short as practical, since the concentration of desirable plasma species may decline with distance from reactor cavity 1053. Generating the cleaning plasma in a remote cavity allows the use of an efficient microwave generator and does not subject chamber components to the temperature, radiation, or bombardment of the glow discharge that may be present in a plasma formed in situ. Consequently, relatively sensitive components, such as electrostatic chuck 1020, do not need to be covered with a dummy wafer or otherwise protected, as may be required with an in situ plasma cleaning process. In FIG. 2A, the plasma-cleaning system 1050 is shown disposed above the chamber 1013, although other positions may alternatively be used.

A baffle 1061 may be provided proximate the top nozzle to direct flows of source gases supplied through the top nozzle into the chamber and to direct flows of remotely generated plasma. Source gases provided through top nozzle 1045 are directed through a central passage 1062 into the chamber, while remotely generated plasma species provided through the cleaning gas feed port 1054 are directed to the sides of the chamber by the baffle 1061.

Seasoning the interior of the substrate processing region has been found to improve many high-density plasma deposition processes. The formation of high density silicon-containing films is no exception. Seasoning involves the deposition of silicon oxide on the chamber interior before a deposition substrate is introduced into the substrate processing region. In embodiments, seasoning the interior of the substrate processing region comprises forming a high density plasma in the substrate processing region from a seasoning process gas comprising an oxygen source and a silicon source. The oxygen source may be diatomic oxygen (O₂) and the silicon source may be silane (SiH₄), though other precursors may also suffice.

Those of ordinary skill in the art will realize that processing parameters can vary for different processing chambers and different processing conditions, and that different precursors can be used without departing from the spirit of the invention. Appropriate silicon containing precursors may include trisilylamine (TSA, (SiH₃)₃N) and disilane (Si₂H₆) in addition to silane. The silicon-containing precursor may be any precursor which consists of silicon and hydrogen in disclosed embodiments. The silicon-containing precursor may consist of silicon, hydrogen and nitrogen in embodiments of the invention. Similarly, the silicon-containing precursor may consist of silicon, hydrogen and carbon or the silicon-containing precursor may consist of silicon, hydrogen and oxygen in disclosed embodiments. Other variations will also be apparent to persons of skill in the art. These equivalents and alternatives are intended to be included within the scope of the present invention. Therefore, the scope of this invention should not be limited to the embodiments described, but should instead be defined by the following claims.

The term “trench” is used throughout with no implication that the etched geometry has a large horizontal aspect ratio. Viewed from above the surface, trenches may appear circular, oval, polygonal, rectangular, or a variety of other shapes. The term “via” is used to refer to a low aspect ratio trench which may or may not be filled with metal to form a vertical electrical connection. As used herein, a conformal layer refers to a generally uniform layer of material on a surface in the same shape as the surface, i.e., the surface of the layer and the surface being covered are generally parallel. A person having ordinary skill in the art will recognize that the deposited material likely cannot be 100% conformal and thus the term “generally” allows for acceptable tolerances. In disclosed embodiments, thinnest portions of “conformal” layers herein may be within 10% or 20% of the thickest portions of the same “conformal” layer.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the precursor” includes reference to one or more precursor and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of depositing a dielectric layer on a metal surface of a substrate in a substrate processing region of a substrate processing chamber, the method comprising the sequential steps of:
transferring the substrate into the substrate processing region;
deoxidizing the substrate with a deoxidation high-density plasma to remove an oxidation layer, wherein the deoxidation high-density plasma comprises hydrogen (H) but is silicon-free, carbon-free, nitrogen-free, fluorine-free and oxygen-free;
forming the dielectric layer on the substrate in the same substrate processing region used for treating the substrate by forming a deposition high density plasma in the substrate processing region from a deposition process gas comprising a silicon source;
removing the substrate from the substrate processing region.

2. The method of claim 1 wherein the deoxidation high-density plasma consists of hydrogen and an inert gas.

3. The method of claim 1 wherein the deposition process gas further comprises at least one of a nitrogen source, an oxygen source or a carbon source.

4. The method of claim 1 wherein the metal surface comprises copper, aluminum or tungsten.

5. The method of claim 1 wherein the metal surface has an electrical resistivity below one hundred nanoohm-meters.

6. The method of claim 1 wherein the dielectric layer is one of silicon oxide, silicon oxynitride, silicon oxycarbide, silicon nitride, silicon carbide or silicon carbon nitride.

7. The method of claim 1 wherein the dielectric layer is conformal with a thickness less than or about ten nanometers.

8. The method of claim 1 wherein forming the deposition high-density plasma comprises applying a total RF power between about 5,000 watts and about 13,000 watts to the substrate processing region while forming the dielectric layer.

9. The method of claim 1, wherein the substrate is electrically biased from the deposition high density plasma with a deposition bias power below or about 500 watts while forming the dielectric layer.

10. The method of claim 1 wherein forming the deoxidation high-density plasma comprises applying RF power between about 5,000 watts and about 13,000 watts to the substrate processing region while deoxidizing the substrate.

11. The method of claim 1, wherein the substrate is electrically biased from the deoxidation high density plasma with a deoxidation bias power below or about 500 watts while deoxidizing the substrate.

12. The method of claim 1 wherein the dielectric layer is a silicon nitride layer.

13. The method of claim 1 further comprising an interfacial preparation step between deoxidizing the substrate and forming the dielectric layer, wherein the interfacial preparation step comprises:
treating the substrate with an interfacial high-density plasma, wherein the interfacial high-density plasma comprises hydrogen (H) and nitrogen (N) formed from an interfacial preparation process gas, wherein the interfacial high-density plasma is fluorine-free.

14. The method of claim 13 wherein the interfacial preparation process gas comprises ammonia.

15. The method of claim 13 wherein a pressure within the substrate processing region is below or about 50 mTorr while treating the substrate, deoxidizing the substrate or forming the dielectric layer.
